(19) United States
(12) Patent Application Publication
(10) Pub. No.: US 2026/0282940 A1
(43) Pub. Date: Sep. 17, 2026

(54) METHOD FOR FABRICATING INTERPOSER, METHOD FOR FABRICATING CHIP, INTERPOSER, CHIP AND CHIP PACKAGE

(71) Applicant: Beijing Huafeng Integrated Electronics Co., LTD., Beijing (CN)

(72) Inventors: Zuoming ZHAO, Beijing (CN); Fay HUA, Beijing (CN)

(21) Appl. No.: 19/473,624

(22) PCT Filed: Apr. 10, 2024
(86) PCT No.: PCT/CN2024/086899

§ 371 Date: Oct. 8, 2025

(30) Foreign Application Priority Data
Apr. 10, 2023 (CN) 202310369310.X
Apr. 10, 2023 (CN) 202310369317.1

(51) Int. Cl. H10W 70/06; H10P 72/70; H10W 70/05; H10W 70/60; H10W 70/695; H10W 90/00; H10W 90/10

(52) U.S. Cl. CPC H10W 70/06; H10P 72/743; H10P 72/7442; H10W 70/096; H10W 70/611; H10W 70/695; H10W 90/10; H10W 90/401

(57) ABSTRACT

The present disclosure relates to a method for fabricating an interposer, a method for fabricating a chip, an interposer, a chip, and a chip package. The method includes the following steps: S1, providing a first carrier, where the first carrier includes a first portion and a second portion, the first portion being an outer edge of one side of the first carrier, and the second portion being a plane of the side defined by the outer edge; S2, adding a first release adhesive to the first portion, adding a first metal film to the second portion, and curing the first release adhesive; S3, adding a first dielectric layer to a surface of the first metal film; S4, preparing a first redistribution layer on the first dielectric layer; S5, removing the current first portion, where the current first portion at least includes the first release adhesive attached thereon; and S6, peeling off the current second portion, and cutting to form the interposer. The method can allow for rapid peeling of the first carrier without high temperature or laser to obtain an organic interposer with a thickness less than 30 microns.

### TECHNICAL FIELD

The present disclosure relates to the technical field of chips, and in particular, to a method for fabricating an interposer, a method for fabricating a chip, an interposer, a chip, and a chip package.

### BACKGROUND

In the field of chip fabrication, both multi-chip packaging and fan-out processes require carriers to support. This specifically includes connecting a plurality of chips or interposers by employing a wafer process or a panel-level process. The chips or interposers are fixed onto a carrier through an organic adhesive, and the carrier is then separated by breaking the adhesive property of the organic adhesive using high temperature or laser, resulting in the desired chips or interposers. This method needs to be implemented at a high temperature, which can alter a structure with a redistribution layer (RDL) and a dielectric layer under the condition of high temperature, thereby affecting the performance of a chip. When the interposer is thinner, it can be damaged to cause delamination or breakage, and thus cannot be successfully peeled off from the carrier.

In the prior art, an embedded multi-die interconnect bridge (EMIB) is usually employed to embed a small passive bridge chip prepared on a silicon substrate into the substrate, making it part of the substrate for connecting a plurality of sub-chips. This process is complex in fabrication, and requires embedding a silicon bridge during the process of substrate fabrication. In addition, during the process of fabrication, since the thermal expansion coefficient of silicon in silicon bridge is smaller and the thermal expansion coefficient of the substrate material is larger, which is generally more than six times that of the silicon bridge, significant stress can be generated during heating and cooling. This can lead to the breakage of copper via connections of the silicon bridge connected to surface sub-chips or the delamination of a dielectric layer.

### SUMMARY

The objectives of embodiments of the present disclosure are to provide a method for fabricating an interposer, an interposer, and a chip package. The method can allow for rapid peeling of a carrier to obtain an ultra-thin interposer for the integration of a plurality of high-performance chips.

In order to achieve the above objectives, the embodiments of the present disclosure provide a method for fabricating an interposer. The method includes the following steps: S1, providing a first carrier, where the first carrier includes a first portion and a second portion, the first portion being an outer edge of one side of the first carrier, and the second portion being a plane of the side defined by the outer edge; S2, adding a first release adhesive to the first portion, adding a first metal film to the second portion, and curing the first release adhesive; S3, adding a first dielectric layer to a surface of the first metal film; S4, preparing a first redistribution layer on the first dielectric layer; S5, removing the current first portion, where the current first portion at least includes the first release adhesive attached thereon; and S6, peeling off the current second portion, and cutting to form the interposer.

Optionally, for Step S1, the first carrier prepared from at least one of silicon, glass, metal or organic plastic is provided.

Optionally, for Step S2, the first metal film is added by vacuum film lamination.

Optionally, for Step S2, the first release adhesive is added by spraying resin or attaching a dry film.

Optionally, for Step S3, the first dielectric layer is added by vacuum roller lamination or spin coating.

Optionally, for Step S3, the first dielectric layer is prepared by coating at least one of polyimide, benzocyclobutene or resin materials.

Optionally, the first portion has a width ranging from 2 mm to 10 mm.

According to another aspect, the present disclosure provides an interposer, which is fabricated according to the above method for fabricating an interposer.

According to another aspect, the present disclosure also provides a chip package, which includes a first substrate, at least one chip, and the above interposer.

The present disclosure provides a method for rapidly peeling off a first carrier, which does not damage a structure with a redistribution layer (RDL) and a dielectric layer, thereby making the performance of a chip more stable.

The objectives of the embodiments of the present disclosure are to provide a method for fabricating a chip, and a chip. The method reduces the stress on a connection bridge, thereby improving the reliability of the chip.

In order to achieve the above objectives, the embodiments of the present disclosure provide a method for fabricating a chip. The method includes the following steps: S71, providing a second substrate and an organic connection bridge, each internally provided with built-in redistribution wires and externally provided with connection points; S72, placing the organic connection bridge on a surface of the second substrate; S73, fixing at least two bare dies on the second substrate, where pins of each bare die are connected to the connection points on both the second substrate and the organic connection bridge; and S74, protecting the pins of the bare dies and the connection points on both the second substrate and the organic connection bridge.

Optionally, for Step S71, providing the organic connection bridge includes: S721, providing a second carrier, where the second carrier includes a third portion and a fourth portion, the third portion being the outer edge of one side of the second carrier, and the fourth portion being a plane of the side defined by the outer edge; S722, adding a second release adhesive to the third portion, adding a second metal film to the fourth portion, and curing the second release adhesive; S723, adding a second dielectric layer on a surface of the second metal film; S724, preparing a second redistribution layer on the second dielectric layer; S725, removing the current third portion, where the current third portion at least includes the second release adhesive attached thereon; and S726, peeling off the current fourth portion, and cutting to form the organic connection bridge.

Optionally, for Step S72, the organic connection bridge is embedded in a groove formed in the surface of the second substrate or directly mounted on the surface of the second substrate.

Optionally, the groove of the second substrate has a depth ranging from 5 microns to 30 microns.

Optionally, for Step S74, the connections between the pins of the bare dies and the connection bridge are protected by mold encapsulation and/or underfill.

Optionally, for Step S73, the bare dies are connected to the second substrate and the organic connection bridge through respective soldering points by arranging the connection points on the surface of the second substrate and the organic connection bridge.

Optionally, dielectric materials of both the organic connection bridge and the second substrate are organic materials, and thermal expansion coefficients of the second substrate and the organic connection bridge are matched.

The present disclosure also provides a chip, which includes: a second substrate and an organic connection bridge arranged on a surface of the second substrate, where each of the second substrate and the organic connection bridge is internally provided redistribution wires and externally provided with connection points; and at least two bare dies fixed on the surface of the second substrate, where pins of each bare die are connected to the connection points on both the second substrate and the organic connection bridge.

Optionally, the organic connection bridge is arranged in a groove formed in one side of the second substrate, or mounted on one side of the second substrate.

Optionally, the groove of the second substrate has a depth ranging from 5 microns to 30 microns.

The method provided by the embodiments of the present disclosure enables signal transmission between chips through the organic connection bridge, and the thermal expansion coefficients of the organic connection bridge and the second substrate are matched, thereby avoiding stress caused by thermal expansion, and improving the reliability of the chip.

Other features and advantages of the embodiments of the present disclosure will be described in detail in the following detailed description.

### BRIEF DESCRIPTION OF THE DRAWINGS

Exemplary descriptions will be made for one or more embodiments through corresponding images in the accompanying drawings. These exemplary descriptions do not constitute limitations to the embodiments. Elements with the same reference numerals in the accompanying drawings represent similar elements, unless stated otherwise. The accompanying drawings do not constitute a limitation on scale.

FIG. 1 is a schematic flowchart of a method for fabricating an interposer according to the present disclosure.

FIG. 2 is a schematic diagram showing edge coating of a first carrier according to the present disclosure.

FIG. 3 is a schematic diagram of vacuum film lamination according to the present disclosure.

FIG. 4 is a schematic diagram of the preparation of a first redistribution layer according to the present disclosure.

FIG. 5 is a schematic diagram of the removal of a first portion according to the present disclosure.

FIG. 6 is a schematic diagram of the removal of the first carrier according to the present disclosure.

FIG. 7 is a schematic flowchart of a method for fabricating a chip according to the present disclosure.

FIG. 8 is a schematic flowchart of a method for fabricating a connection bridge according to the present disclosure.

FIGS. 9a to 9d are schematic diagrams of the method for fabricating a connection bridge according to the present disclosure.

FIG. 10 is a schematic diagram of an embodiment of a method for fabricating a chip according to the present disclosure.

FIG. 11 is a schematic diagram of another embodiment of a method for fabricating a chip according to the present disclosure.

FIGS. 12 and 13 are schematic diagrams of a multi-chip connection bridge connection method according to the present disclosure.

### Reference Numerals in the Drawings

101—First carrier; 102—First release adhesive; 103—First metal film; 104—First dielectric layer; 105—To-be-removed portion.

1101—First sub-chip; 1102—Second sub-chip; 1103—Organic connection bridge; 1104—Second substrate; 1105—Third sub-chip; 1106—Fourth sub-chip; 203—First connection bridge; 303—Second connection bridge; 403—Third connection bridge; 503—Fourth connection bridge.

### DETAILED DESCRIPTION OF THE EMBODIMENTS

The specific implementations of embodiments of the present disclosure will be illustrated in detail below with reference to the accompanying drawings. It should be understood that the specific implementations described herein are merely intended to illustrate and explain the embodiments of the present disclosure rather than limit the embodiments of the present disclosure.

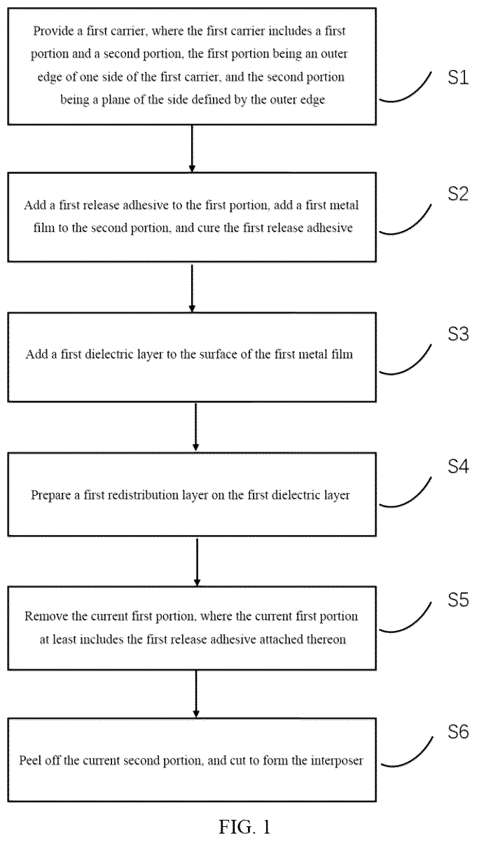

FIG. 1 is a schematic flowchart of a method for fabricating an interposer according to the present disclosure. As shown in FIG. 1, the method for fabricating an interposer provided by the present disclosure includes the following steps.

In step S1, a first carrier 101 is provided, where the first carrier 101 includes a first portion and a second portion, the first portion being the outer edge of one side of the first carrier 101, and the second portion being a plane of the side defined by the outer edge. According to a specific implementation, when the shape of the first carrier 101 is chosen to be round, the first portion is the outer edge of one side of the first carrier 101, which is the rim of the outer edge of the first carrier 101. The first portion has a width ranging from 2 mm to 10 mm, meaning that the width of the rim is 2 mm to 10 mm. For Step S1, providing the first carrier 101 includes: providing the first carrier prepared from at least one of silicon, glass, metal or organic plastic.

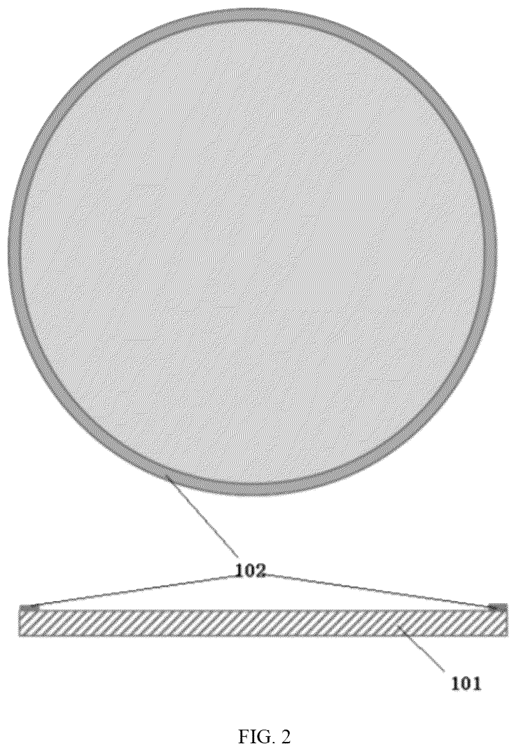

In step S2, a first release adhesive 102 is added to the first portion. FIG. 2 is a schematic diagram showing edge coating of the first carrier 101 according to the present disclosure. The adhesive may be evenly applied by employing a high-precision dispensing method, or aligned and attached by using a pre-cut film adhesive. FIG. 2 shows the first carrier 101 at different observation angles (the upper drawing is a top view, and the lower drawing is a side view). The first release adhesive 102 is applied on the outer edge of one side of the first carrier 101, and the width of the first release adhesive 102 ranges from 2 mm to 10 mm.

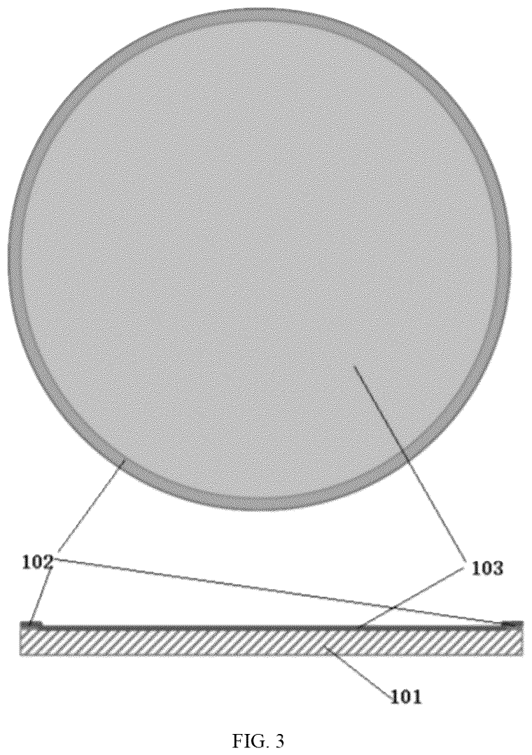

The step S2 also includes: adding a first metal film 103 to the second portion, and curing the first release adhesive 102. FIG. 3 is a schematic diagram of vacuum film lamination according to the present disclosure. As shown in FIG. 3, for Step S2, the first metal film 103 is added by vacuum film lamination. The curing includes: spraying resin or attaching a dry film. The first metal film is preferably copper or aluminum, and the dry film is an organic film, such as a polyimide film or a resin film. An organic film may also be added to the second portion, or a multi-structure film may be added to the second portion. The interior of the multi-structure film is the first metal film 103, and the exterior is the organic film. During the implementation process, the first metal film 103 may also be added first before coating. As long as the first metal film 103 reserves the edge of the first portion, the same technical effect of sealing the first metal film 103 on the first carrier can be achieved. As shown in FIG. 3, the carrier structure formed by the present disclosure has the first release adhesive only in the area of the first portion less than 10 mm at the edge, while the area of the second portion does not have any adhesive. This can ensure the flatness of the second portion and prevent any deformation introduced by the curing of the adhesive.

In step S3, a first dielectric layer 104 is added to a surface of the first metal film 103. For Step S4, the first dielectric layer 104 is added by vacuum roller lamination or spin coating. The first dielectric layer 104 may be at least one of polyimide, benzocyclobutene or resin materials. The first dielectric layer is provided with a circuit pattern. The circuit pattern is arranged in the second portion, and due to the excellent flatness of this portion, a circuit design with higher precision than the prior art can be made.

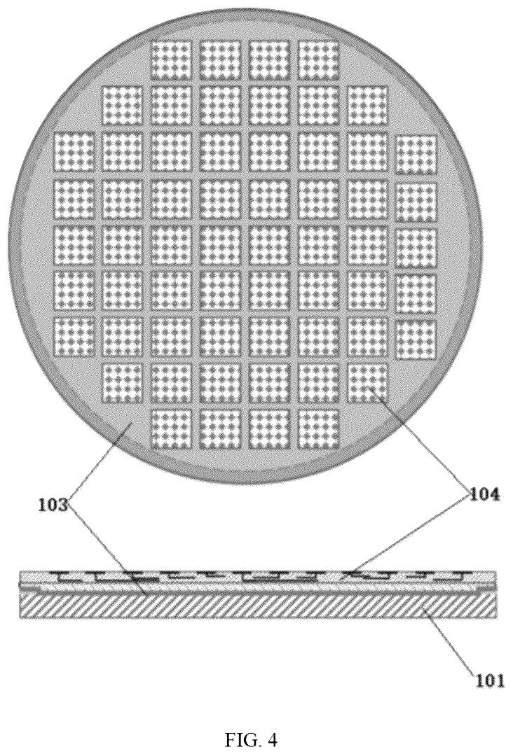

In step S4, a first redistribution layer (RDL) is prepared on the first dielectric layer 104. FIG. 4 is a schematic diagram of the preparation of the first redistribution layer according to the present disclosure. A plurality of RDLs are prepared by photolithography and electroplating processes, and an interposer structure is generated as shown in FIG. 4. The generated interposer is provided with connection points that can be connected with the outside and are used to connect chips or a first substrate. The specific design for the preparation of the first redistribution layer is determined according to the function of the interposer. The interposer may be a bridge for lateral chip connections, a redistribution wire for vertical transmission of the chip, or a groove for vertical signal transmission.

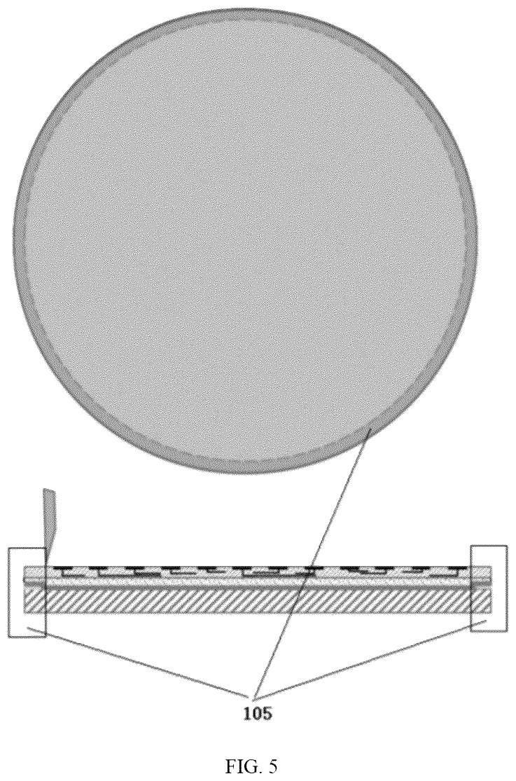

In step S5, the current first portion is removed, where the current first portion at least includes the first release adhesive 102 attached thereon. As shown in FIG. 5, the current first portion is a to-be-removed portion 105. The removal of the current first portion may include: removing the first release adhesive 102, or cutting off the current first portion.

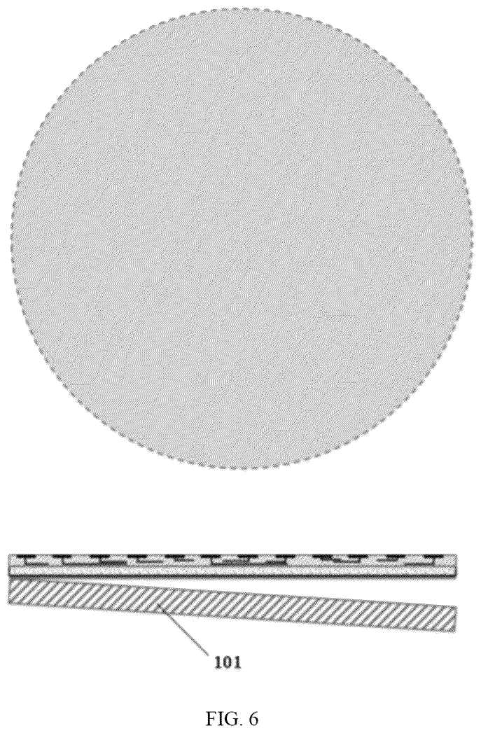

In step S6, the current second portion is peeled off and cut to form a first interposer. No external force is required for peeling. After the first portion is removed, an interface between the metal of the second portion and the first carrier can be automatically separated. As shown in FIG. 6, the current second portion is a part of the carrier. Peeling off this part of the carrier and then etching to remove the remaining metal film layer on the back yield the final interposer, and the interposer can then be cut and used for further processing.

This application also proposes an interposer, which is fabricated according to the above method for fabricating an interposer.

This application also proposes a chip package, which includes a first substrate, at least one chip, and the above interposer, where both the interposer and the chip are arranged on the first substrate.

The present disclosure provides a method for rapidly peeling off the first carrier 101, which does not damage the structure with the redistribution layer (RDL) and the first dielectric layer 104. In this method, after the first portion is removed, the second portion can be automatically separated due to the absence of the first release adhesive in the second portion and then the absence of chemical bonding between the first metal film of the second portion and the first carrier. The interposer generated on the surface is not subjected to external stress during separation, can be transferred to a first cutting film for cutting, and then is mounted to the used interface by employing the flip-chip process. Since this process does not introduce external stress during the production process an interposer smaller than 30 microns can be prepared without breakage or delamination.

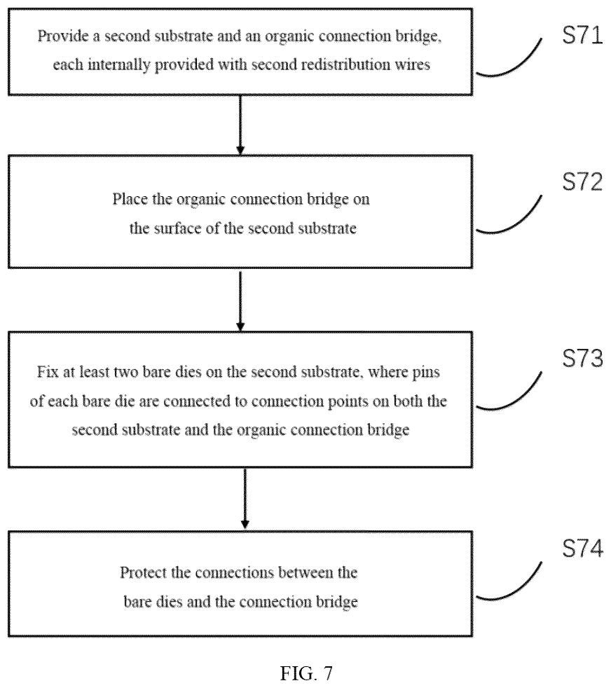

FIG. 7 is a schematic flowchart of a method for fabricating a chip according to the present disclosure. As shown in FIG. 7, the method for fabricating the chip according to the present disclosure includes the following steps.

In step S71, a second substrate 1104 and an organic connection bridge 1103, each internally provided with a redistribution wire, are provided. Dielectric materials of both the organic connection bridge 1103 and the second substrate 1104 are organic materials. When the organic connection bridge is designed, an appropriate organic material and a wiring structure may be chosen to match thermal expansion coefficients of the organic connection bridge 1103 and the second substrate 1104, so that the organic connection bridge 1103 adopting this design can avoid stress caused by thermal expansion.

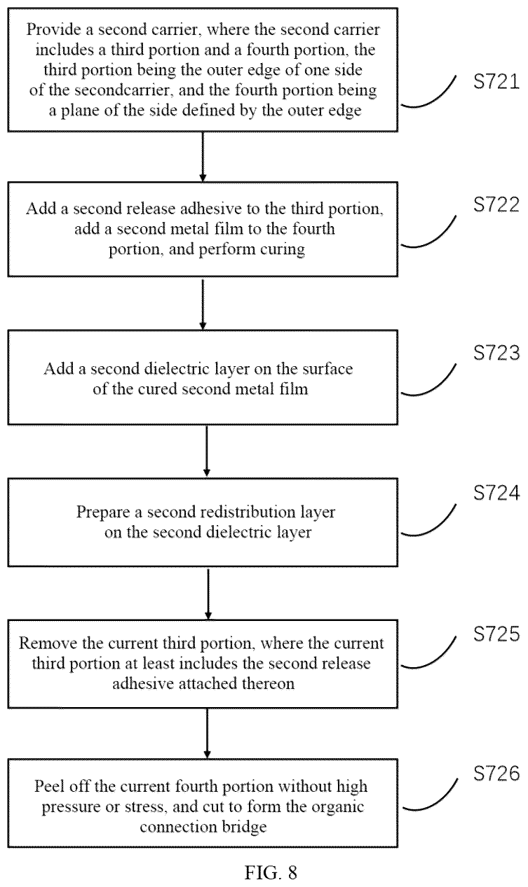

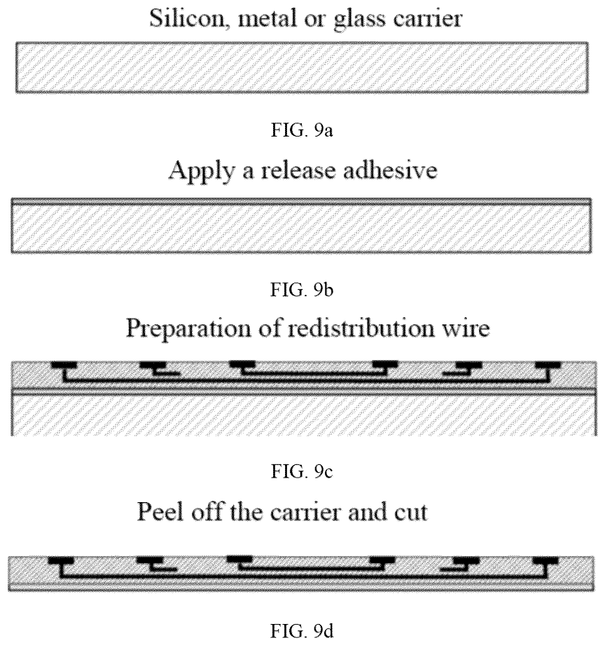

For Step S71, as shown in FIG. 8, providing the organic connection bridge 1103 includes: S721, providing a second carrier, where the second carrier includes a third portion and a fourth portion, the third portion being the outer edge of one side of the second carrier, and the fourth portion being a plane of the side defined by the outer edge; S722, adding a second release adhesive to the third portion; S723, adding a second metal film to the fourth portion, and curing the second release adhesive; S724, adding a second dielectric layer on a surface of the second metal film; S725, preparing a second redistribution layer on the second dielectric layer; S726, removing the current third portion, where the current third portion at least includes the second release adhesive attached thereon; and S727, peeling off the current fourth portion, and cutting to form the organic connection bridge 1103. Specifically, as shown in FIGS. 9a to 9d, providing the second carrier includes: providing the second carrier prepared from at least one of silicon, glass, metal or organic plastic. Multi-layer redistribution wires are prepared by photolithography and electroplating processes to generate an interposer structure. Finally, the second carrier is peeled off to obtain the organic connection bridge 1103. This preparation process only has the second release adhesive at the edge of the second carrier, and no second release adhesive in the area where the organic connection bridge 1103 is prepared. The middle area is laminated on the second carrier in vacuum, and the edge is then sealed to form the second carrier. Therefore, the second carrier can be peeled off without high temperature or stress. This solution can peel off the organic connection bridge 1103 smaller than 30 microns.

The present disclosure uses mature packaging and the back-end wafer processes to fabricate the interposer. The allows for line width and spacing of less than 1 um to 2 um, enabling the preparation of high-density and high-bandwidth I/O grooves. Moreover, according to the method, the bridge chip is prepared by choosing an organic material matched with the thermal expansion coefficient of the second substrate 1104. Finally, the second carrier is removed. The whole connection bridge is composed of the organic dielectric material and copper wiring, without materials with smaller thermal expansion coefficients (such as silicon). Consequently, stress on the organic connection bridge 1103 from the second substrate 1104, underfill or plastic packaging can be avoided, thereby improving the reliability of the chip.

In step S72, the organic connection bridge 1103 is placed on a surface of the second substrate 1104. According to a specific implementation, the organic connection bridge 1103 is embedded in a groove formed in the surface of the second substrate 1104, or directly mounted on the surface of the second substrate 1104. If a chip design allows for larger spacing and higher connection points (for example, the connection height between the chip and the second substrate 1104 is greater than 70 microns) for a user, the organic connection bridge 1103 may be directly mounted in a reserved area of the second substrate 1104 without making any changes to the second substrate 1104. Alternatively, if bumps used to connect the chips with the second substrate 1104 are smaller than 70 microns after connection, the reserved area of the second substrate 1104 may be modified. This can involve reserving a groove when preparing the second substrate 1104. The thickness of this groove and a surface passivation layer (such as solder resist) is approximately less than 30 microns. It is only required to reserve the area for the organic connection bridge 1103 during the final passivation layer photolithography and remove the surface passivation layer or use laser grooving to remove part of the surface passivation layer to accommodate the organic connection bridge 1103. Preferably, the groove of the second substrate 1104 has a depth ranging from 5 microns to 30 microns, and may be designed according to the height of the connection points between the chip and the second substrate 1104. The surface of the second substrate 1104 and the organic connection bridge 1103 are provided with soldering points for connecting the sub-chips with the second substrate 1104 and the organic connection bridge 1103 respectively.

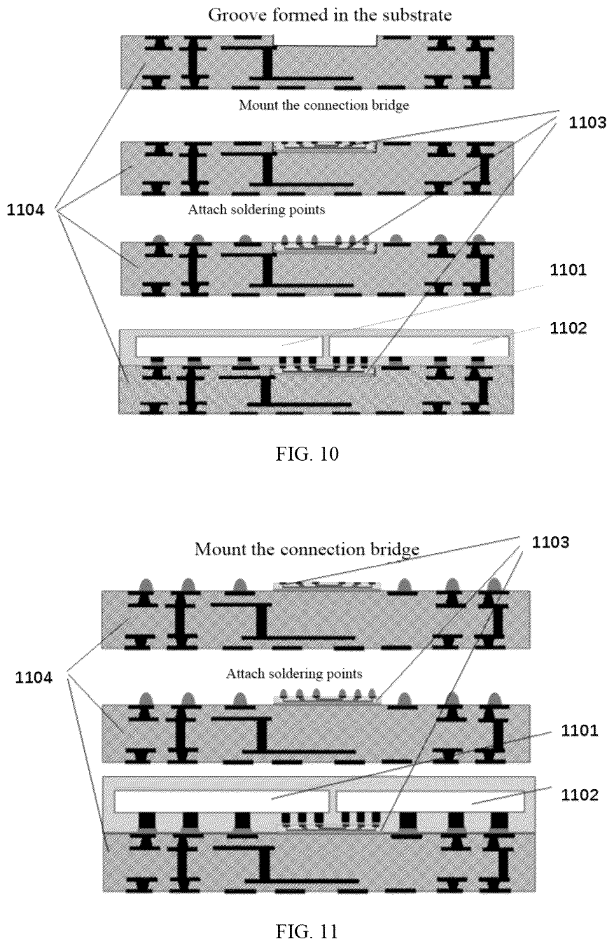

FIG. 10 shows embedding the organic connection bridge 1103 in a groove formed in the second substrate 1104, which specifically includes: forming a groove in the second substrate 1104, where the size of the groove is determined according to the size of the organic connection bridge 1103. An adhesive is applied onto the inner wall of the groove, and the organic connection bridge 1103 is placed to adhere to the adhesive. Redistribution wires are arranged in both the second substrate 1104 and the organic connection bridge 1103, soldering points are attached to a surface where the redistribution wires of the two are routed out, and finally sub-chips (i.e. a first sub-chip 1101 and a second sub-chip 1102) are arranged. The groove in the surface may be formed in the second substrate 1104 in advance or using laser grooving at the later stage. The depth of the groove may also be flexibly adjusted according to the height of the soldering points and the thickness of the organic connection bridge 1103, and the step height of bridge chip can also vary from 0 microns to 30 microns depending on the designs.

FIG. 11 is a schematic diagram illustrating directly mounting the organic connection bridge onto the surface of the second substrate, which specifically includes: directly mounting the organic connection bridge 1103 onto the second substrate 1104, where redistribution wires are arranged in both the second substrate 1104 and the organic connection bridge 1103, soldering points are attached to a surface where the redistribution wires of the second substrate 1104 and the organic connection bridge 1103 are routed out, and finally the sub-chips (the first sub-chip and the second sub-chip 1102) are arranged.

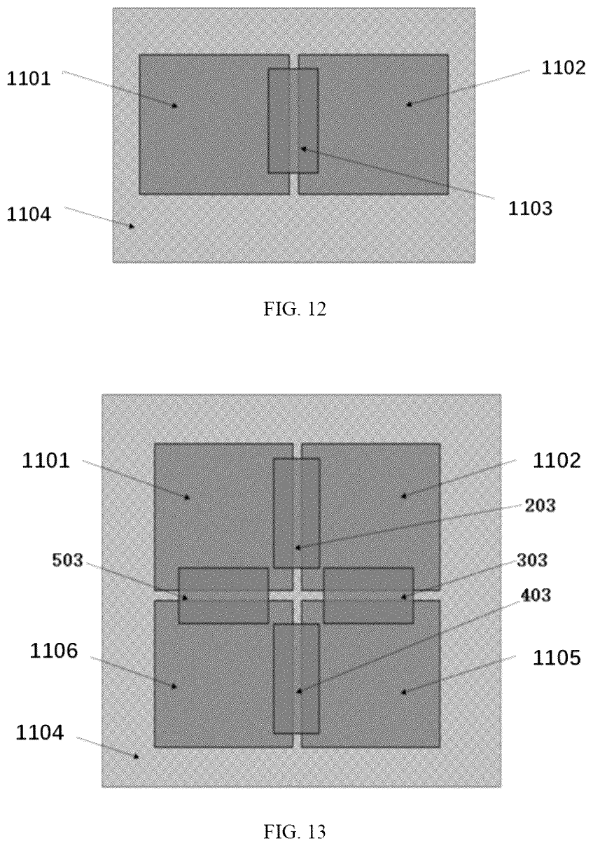

In step S73, at least two sub-chips are fixed on the second substrate 1104, where pins of each sub-chip are connected to the redistribution wires in the second substrate 1104 and the organic connection bridge 1103. This application can also be used for connecting a plurality of small sub-chips. For example, four sub-chips with a size of 15 mm x 15 mm may be connected to form a large chip with a size of 30 mm×30 mm, as shown in FIG. 12.

In step S74, the connections between the pins of the bare dies and the connection bridge 1103 are protected. For Step S74, the protection may be achieved by mold encapsulation and/or underfill (as shown in FIGS. 11 and 12). After this step, the chip may be connected to a motherboard or other circuits through the connection points on the other side of the second substrate 1104, and solder balls, contact pads or pins may be arranged on the connection points, which are conventional arrangements and will not be further elaborated.

The present disclosure further provides a chip, which includes: a second substrate 1104 and an organic connection bridge 1103 arranged on a surface of the second substrate 1104, where each of the second substrate 1104 and the organic connection bridge 1103 is externally provided with redistribution wires and externally provided with connection points; and at least two sub-chips fixed on the surface of the second substrate 1104, where pins of each sub-chip are connected to the connection points on the second substrate 1104 and the organic connection bridge 1103, and signal transmission between the chips is enabled through the redistribution wires. The organic connection bridge 1103 is arranged in a groove formed in one side of the second substrate 1104, or mounted on one side of the second substrate 1104. As shown in FIG. 12, a first sub-chip 1101 and a second sub-chip 1102 in FIG. 12 are connected through the organic connection bridge 1103. The organic connection bridge 1103 is embedded in a groove formed in the surface of a second substrate 1104, or directly mounted on the surface of the second substrate 1104, and the three are arranged on the second substrate 1104. In FIG. 13, a first sub-chip 1101 and a second sub-chip 1102 are connected through a first connection bridge 203, the first sub-chip 1101 and a fourth sub-chip 1106 are connected through a fourth connection bridge 503. The second sub-chip 1102 and a third sub-chip 1105 are connected through a second connection bridge 303, and the third sub-chip 1105 and the fourth sub-chip 1106 are connected through a third connection bridge 403. The connection bridges (i.e. organic connection bridges including the first connection bridge 203, the second connection bridge 303, the third connection bridge 403, and the fourth connection bridge 503) are embedded in grooves formed in the surface of the second substrate, or directly mounted on the surface of the second substrate 1104. The grooves in the second substrate 1104 have a depth ranging from 5 microns to 30 microns.

Since the method for fabricating the chip according to the present disclosure only uses an organic dielectric layer and wires to prepare the organic connection bridge 1103, an appropriate organic dielectric layer can be chosen to match the thermal expansion coefficient of the second substrate 1104, and a plurality of high-power chips (such as CPU, GPU or AI chips) are connected together to generate a chip with higher performance. When such a high-performance chip generates heat, the materials in the chip can undergo thermal expansion and contraction. This method does not generate stress on the connection bridge due to different thermal expansion coefficients, resulting in the chip with higher reliability.

Optional implements of the embodiments of the present disclosure have been described in detail above with reference to the accompanying drawings. However, the embodiments of the present disclosure are not limited to the specific details in the above embodiments. Within the technical concept of the embodiments of the present disclosure, various simple variations can be made to the technical solutions of the embodiments of the present disclosure, and all these simple variations fall within the protection scope of the embodiments of the present disclosure.

It should also be noted that all the specific technical features described in the above specific implementations can be combined in any suitable manner without contradiction. In order to avoid unnecessary repetition, various possible combinations will not be further elaborated in embodiments of the present disclosure.

It should also be noted that the terms “comprise,” “include” or any other variants thereof herein are intended to cover non-exclusive inclusion, so that a process, method, article or device including a series of elements includes not only those elements but also other elements not explicitly listed or elements inherent to such process, method, article or device. Without more restrictions, the elements defined by the phrase “include a/an . . . ” do not exclude the presence of other identical elements in the process, method, article or device including the elements.

The above are only embodiments of the present application rather than used to limit this application. For those skilled in the art, the present application can have various modifications and variations. Any modification, equivalent, improvement and the like made within the spirit and principle of this application shall fall within the scope of the claims of this application.

What is claimed:

1. A method for fabricating an interposer, comprising:
S1, providing a first carrier, wherein the first carrier comprises a first portion and a second portion, the first portion being an outer edge of one side of the first carrier and the second portion being a plane of the side defined by the outer edge;
S2, adding a first release adhesive to the first portion, adding a first metal film to the second portion, and curing the first release adhesive;
S3, adding a first dielectric layer to a surface of the first metal film;
S4, preparing a first redistribution layer on the first dielectric layer;
S5, removing the current first portion, wherein the current first portion at least comprises the first release adhesive attached thereon; and
S6, peeling off the current second portion, and cutting to form the interposer.

2. The method according to claim 1, wherein for Step S1, the first carrier fabricated from at least one of silicon, glass, metal or organic plastic is provided.

3. The method according to claim 1, wherein for Step S2, the first metal film is added by vacuum film lamination.

4. The method according to claim 1, wherein for Step S2, the first release adhesive is added by spraying resin or attaching a dry film.

5. The method according to claim 1, wherein for Step S3, the first dielectric layer is added by vacuum roller lamination or spin coating.

6. The method according to claim 1, wherein for Step S3, the first dielectric layer is prepared by coating at least one of polyimide, benzocyclobutene or resin materials.

7. The method according to claim 1, wherein the first portion has a width ranging from 2 mm to 10 mm.

8. An interposer, fabricated by the method for fabricating an interposer according to claim 1.

9. A chip package, comprising a first substrate, at least one chip, and the interposer according to claim 8.

10. A method for preparing a chip, comprising:
S71, providing a second substrate and an organic connection bridge, each internally provided with redistribution wires and externally with connection points;
S72, placing the organic connection bridge on a surface of the second substrate;
S73, fixing at least two bare dies on the second substrate, wherein pins of each bare die are connected to the connection points on both the second substrate and the organic connection bridge; and
S74, protecting the connections between the bare dies and the connection bridge;
for Step S71, providing the organic connection bridge comprises:
S721, providing a second carrier, wherein the second carrier comprises a third portion and a fourth portion, the third portion being the outer edge of one side of the second carrier, and the fourth portion being a plane of the side defined by the outer edge;
S722, adding a second release adhesive to the third portion, adding a second metal film to the fourth portion, and curing the second release adhesive;
S723, adding a second dielectric layer on a surface of the second metal film;
S724, preparing a second redistribution layer on the second dielectric layer;
S725, removing the current third portion, wherein the current third portion at least comprises the second release adhesive attached thereon; and
S726, peeling off the current fourth portion without high pressure and stress, and cutting to form the organic connection bridge.

11. The method according to claim 10, wherein for Step S72, the organic connection bridge is embedded in a groove formed in the surface of the second substrate, or directly mounted on the surface of the second substrate.

12. The method according to claim 11, wherein the groove of the second substrate has a depth ranging from 5 microns to 30 microns.

13. The method according to claim 10, wherein for Step S74, the connections between the bare dies and the connection bridge are protected by mold encapsulation and/or underfill.

14. The method according to claim 10, wherein for Step S73, the bare dies are connected to the second substrate and the organic connection bridge through respective soldering points by arranging the connection points on the surface of the second substrate and the organic connection bridge.

15. The method according to claim 10, wherein dielectric materials of both the organic connection bridge and the second substrate are organic materials, and thermal expansion coefficients of the second substrate and the organic connection bridge are matched.

16. A chip, comprising:
a second substrate and an organic connection bridge arranged on a surface of the second substrate, wherein each of the second substrate and the organic connection bridge is internally provided with redistribution wires; and
at least two bare dies fixed on the surface of the second substrate, wherein pins of each bare die are connected to connection points on both the second substrate and the organic connection bridge; and
a method for preparing the organic connection bridge comprises:
S721, providing a second carrier, wherein the second carrier comprises a third portion and a fourth portion, the third portion being the outer edge of one side of the carrier, and the fourth portion being a plane of the side defined by the outer edge;
S722, adding a second release adhesive to the third portion, adding a second metal film to the fourth portion, and curing the second release adhesive;
S723, adding a second dielectric layer on a surface of the second metal film;
S724, preparing a second redistribution layer on the second dielectric layer;
S725, removing the current third portion, wherein the current third portion at least comprises the second release adhesive attached thereon; and
S726, peeling off the current fourth portion without high pressure and stress, and cutting to form the organic connection bridge.

17. The chip according to claim 16, wherein the organic connection bridge is arranged in a groove formed in one side of the second substrate, or the organic connection bridge is mounted on one side of the second substrate.

18. The chip according to claim 16, wherein the groove of the second substrate has a depth ranging from 5 microns to 30 microns.
